(19) United States
(12) Patent Application Publication
(10) Pub. No.: US 2026/0231559 A1
(43) Pub. Date: Aug. 6, 2026

(54) MULTILAYER SOLAR PANEL STACKING SYSTEM

(71) Applicant: Anawat Smanpongse, La Puente, CA (US)

(72) Inventor: Anawat Smanpongse, La Puente, CA (US)

(21) Appl. No.: 19/456,825

(22) Filed: Jan. 22, 2026

Related U.S. Application Data
(60) Provisional application No. 63/752,793, filed on Feb. 2, 2025.

(51) Int. Cl. H10F 77/42; G02B 5/18; H10F 19/40

(52) U.S. Cl. CPC H10F 77/488; H10F 19/40; G02B 5/1861

(57) ABSTRACT

A multilayer solar panel system includes a first solar panel oriented to receive direct sunlight and a second solar panel oriented in an opposite direction relative to the first solar panel. The multilayer solar panel system further includes a light tunnel unit to capture sunlight and guide the sunlight toward a light reflecting unit and a mirror unit. The multilayer solar panel system further includes the light reflecting unit to receive sunlight from the light tunnel and distribute the sunlight toward the second solar panel. The multilayer solar panel further includes the mirror unit to reflect incoming sunlight toward the light reflecting unit and onto the second solar panel.

### CROSS-REFERENCE TO RELATED APPLICATIONS

This present application claims priority to U.S. provisional patent application Ser. No. 63/752,793, filed on Feb. 2, 2025, the entire disclosure of which is incorporated by reference herein in its entirety.

### TECHNICAL FIELD

Embodiments of the present disclosure relate to utilizing refractions of sunlight to energize multiple layers of solar panel stacked within the device.

### BACKGROUND

With conventional solar panel technology, single-sided panels (also referred to as monofacial PV) and double-sided panels (also referred to as bifacial PV) are typically used to convert sunlight to electrical energy. A panel design utilizing different angles may simultaneously energize two or more layers of solar panels stacked back-to-back, thereby increasing efficiency and power output. With real estate becoming less available, new approaches are needed to better utilize available surface area to its maximum potential. As the world transitions toward greener energy sources, there is a growing need for new ways to capture energy and transfer it in an environmentally friendly manner. There is an ongoing effort to improve current methods of capturing renewable energy and advance existing technology. Accordingly, there remains a need for improved systems and methods for converting solar energy that may achieve greater efficiency.

### SUMMARY

The problem stated above is that the efficiency of converting energy from solar to electrical energy and the use of extensive space is becoming a challenge. Accordingly, functional elements of a multilayer solar panel system were considered, looking for elements that could potentially be harnessed to provide a better solution in the method of energy conversion.

The current solar panels technologies in the market today are used with monofacial solar panels and some bifacial solar panels, which consume a wide area of space when all solar panels installed together as the system.

It was recognized that, at the point of activation, a multilayer solar panel may be a solution to increase efficiency of energy conversion versus space used for installations and maximize the bottom line of spaces and installation costs.

Accordingly, in an embodiment of the present disclosure, a system consisting of 4 main components to use in light reflective concept.
1. Multiple layers of solar panels to convert the sunlight into electrical energy.
2. Light tunnel unit to receive solar energy from the sunlight and feed it down to following units.
3. Light reflecting unit receives sunlight from light tunnel unit and distributed the solar energy in two directions, one will reflect the sunlight directly to the internal solar panel, and the other direction will go through the mirror unit to continue directing the sunlight to the other part of the unit.
4. The mirror unit will reflect the sunlight to the light reflecting unit and onto the internal solar panel for the energy conversion.

In one embodiment, the light tunnel unit is designed to capture solar energy from sunlight and redirect it in multiple directions. This redirection is achieved through a configuration of a tunnel with mirrored walls, allowing the sunlight to be reflected down and then refracted toward the diagonal edges and onto other layers.

In one embodiment, the mirror unit is designed to redirect all incoming sunlight from the light tunnel unit and direct it onto the light reflecting unit.

In one embodiment, the light reflecting unit is configured to harvest solar energy by receiving sunlight through mirror units and transparent base portions of pyramid-shaped grating elements. Incoming solar rays are reflected upward and dispersed in multiple directions by the pyramid-shaped grating, thereby directing light to additional areas of the internal solar panel. This arrangement increases the effective illumination area of the internal solar panel and enhances electrical energy conversion efficiency.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIG. 1A depicts an exploded view of the system to show all components, in accordance with some embodiments of the present disclosure.

FIG. 1B depicts a top view of the solar panel to receive solar energy and convert it to electricity, in accordance with some embodiments of the present disclosure.

FIG. 1C depicts a bottom view of the solar panel, in accordance with some embodiments of the present disclosure.

FIG. 2A depicts the top perspective view of the light tunnel unit, in accordance with some embodiments of the present disclosure.

FIG. 2B depicts the bottom perspective view of the light tunnel unit, in accordance with some embodiments of the present disclosure.

FIG. 2C depicts the cross-sectional side view of the light tunnel unit, in accordance with some embodiments of the present disclosure.

FIG. 3A depicts the top perspective view of the light reflecting unit, in accordance with some embodiments of the present disclosure.

FIG. 3B depicts the bottom perspective view of the light reflecting unit, in accordance with some embodiments of the present disclosure.

FIG. 4 depicts an elevation view of an adhesive support layer, in accordance with some embodiments of the present disclosure.

FIG. 5 depicts an elevation view of the mirror unit, in accordance with some embodiments of the present disclosure.

### DETAILED DESCRIPTION OF THE EMBODIMENTS

Aspects of the present disclosure are directed to multilayer solar panel stacking to increase the efficiency of solar energy conversion while reducing the physical space used for installation. The system utilizes light reflection and refraction to direct solar radiation toward multiple photovoltaic (PV) cell layers, thereby optimizing energy capture and conversion. In some embodiments, a diffractive device that features a pyramid-shaped blazed grating to concentrate solar radiation is used to direct the solar radiation toward the PV cells. Depending on the embodiment, the PV cells can be single-sided PV cells (i.e., monofacial PV cells) or double-sided PV cells (i.e., bifacial PV cells).

In conventional solar panel systems, each PV cell includes a thin semiconductor wafer composed of two layers of silicon. One of the silicon layers carries a positive charge, while the other layer is negatively charged, thereby establishing an electric field. When sunlight, or light energy from the sun, strikes a PV cell, it imparts energy to the cell, leading to the release of electrons from atoms within the semiconductor wafer. These liberated electrons are subsequently set into motion by the electric field that surrounds the wafer, and this motion gives rise to the generation of an electrical current.

However, only one side of the solar panel is used to energize and provide converted energy, often at relatively low efficiency levels. The inefficiency of converting solar energy to electrical energy necessitates the use of larger installation areas to achieve desired power output levels. As available real estate becomes increasingly limited, conventional single-layer solar panel installations may not fully utilize the available surface area to its maximum potential.

Aspects of the present disclosure address the above and other deficiencies by increasing the efficiency of energy conversion versus space used for installations. The system includes multiple layers of solar panels to convert sunlight into electrical energy. In some embodiments, the multiple layers of solar panels include an external solar panel oriented toward the sun to receive direct sunlight, and an internal solar panel facing the opposite direction to receive reflected and refracted sunlight within the system. In some embodiments, the internal and external solar panels are bonded together. A light tunnel unit captures sunlight from above and guides it downward through a tunnel with mirrored walls. The mirrored walls reflect sunlight down toward diagonal edges, which are angled to redirect the light onto other components of the system.

In some embodiments, a light reflecting unit receives sunlight from the light tunnel unit and distributes the solar energy in two directions. Along one path, sunlight passes through transparent gaps between pyramid-shaped grating elements to directly illuminate the internal solar panel. Along another path, sunlight reflects off the surfaces of the pyramid-shaped grating elements and disperses in multiple directions, directing light to additional areas of the internal solar panel. A mirror unit positioned below the light reflecting unit reflects incoming sunlight back toward the light reflecting unit and onto the internal solar panel. This arrangement increases the effective illumination area of the internal solar panel and enhances electrical energy conversion efficiency.

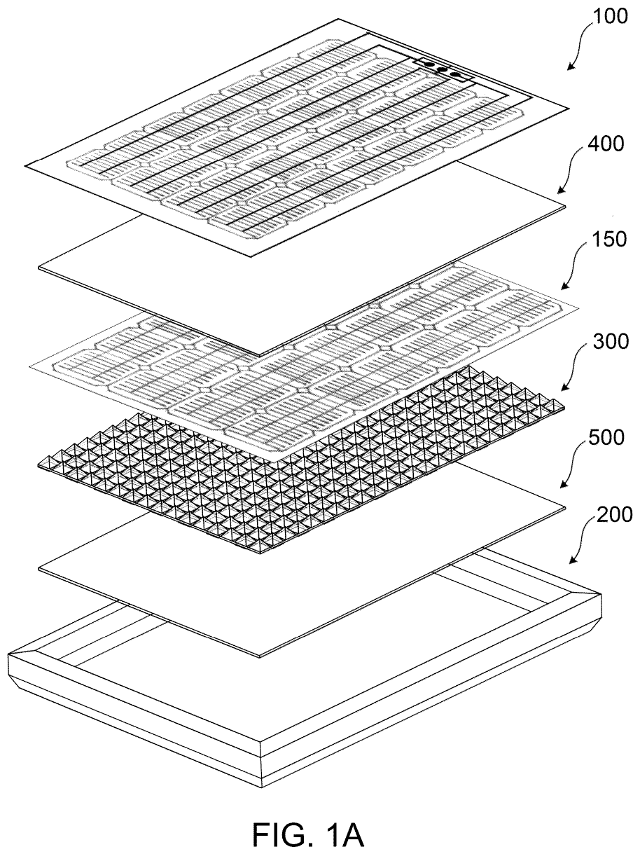

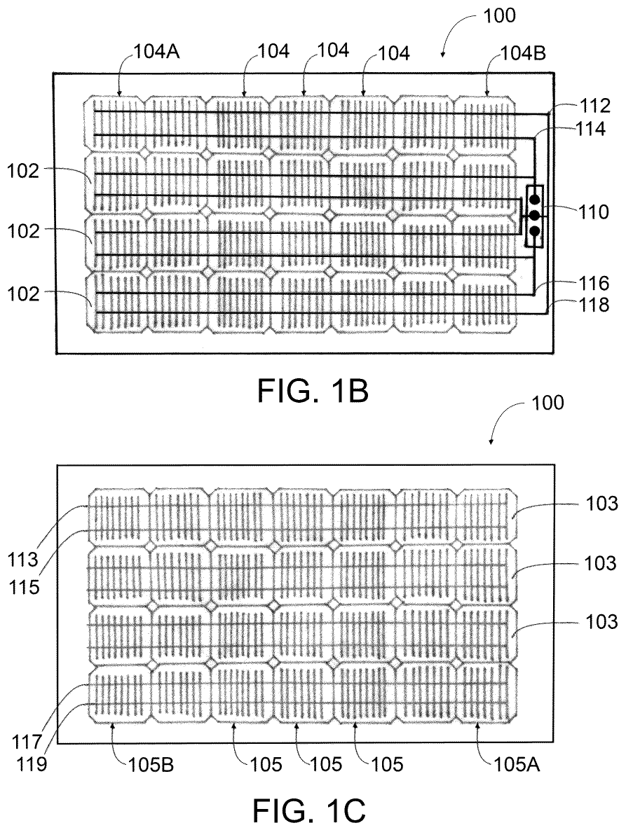

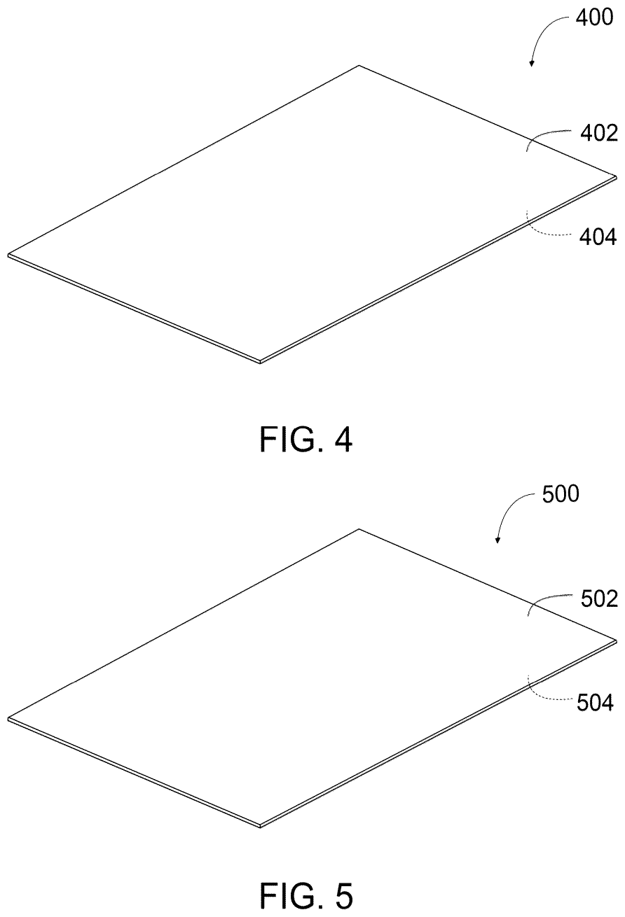

FIG. 1A depicts a multilayer solar panel stacking system, in accordance with embodiments of the present disclosure. The top two layers of the solar panel, denoted as 100 and 150, represent two distinct layers of the solar panel facing in opposite directions. Solar panel 100 is an external solar panel oriented toward the sun to receive direct sunlight. Solar panel 150 is an internal solar panel facing downward to receive reflected and refracted sunlight from within the system. In some embodiments, a translucent adhesive support layer 400 bonds the two solar panels together and energizes the rear side of the bifacial solar cells, if such cells are part of the system. Additional description regarding the translucent adhesive support layer 400 is provided with regard to FIG. 4.

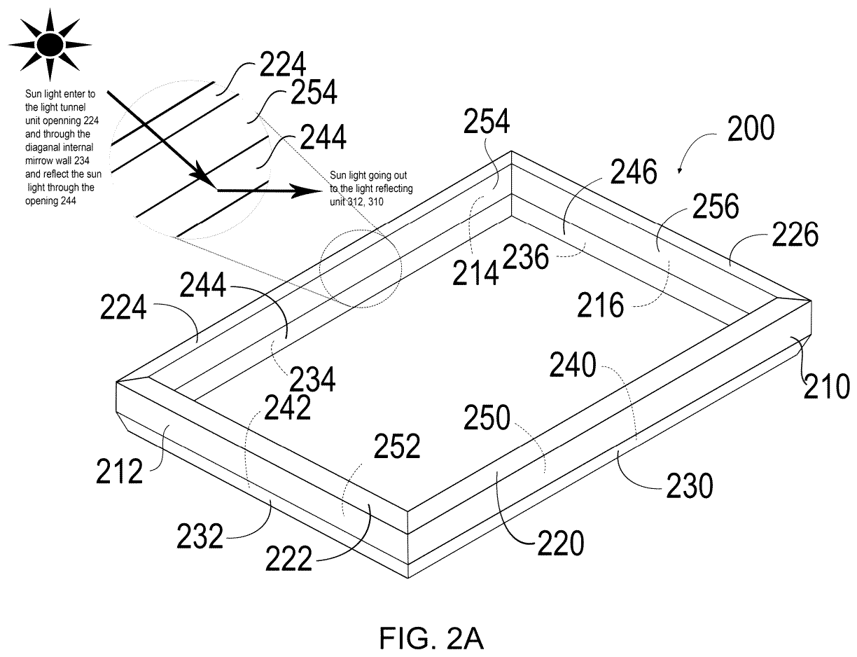

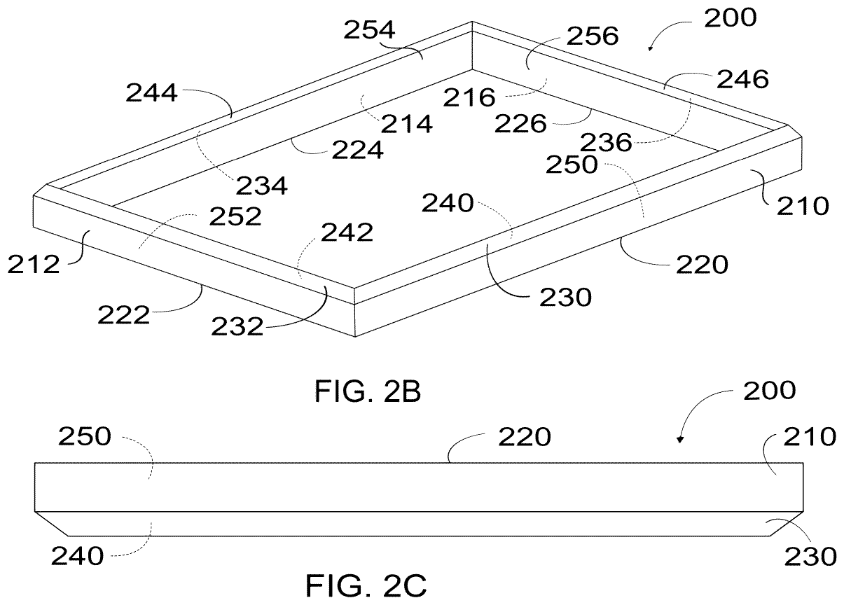

In some embodiments, a light tunnel unit 200 is positioned at the bottom of the assembly and captures sunlight from upper surfaces, guiding it downward through reflective internal walls. Diagonal mirror walls redirect the sunlight toward the outgoing light surfaces, which direct light onto the light reflecting unit 300 and the mirror unit 500. This design enables the simultaneous energizing of multiple solar panels. Further description regarding the light tunnel unit 200 is provided with regard to FIGS. 2A, 2B, and 2C.

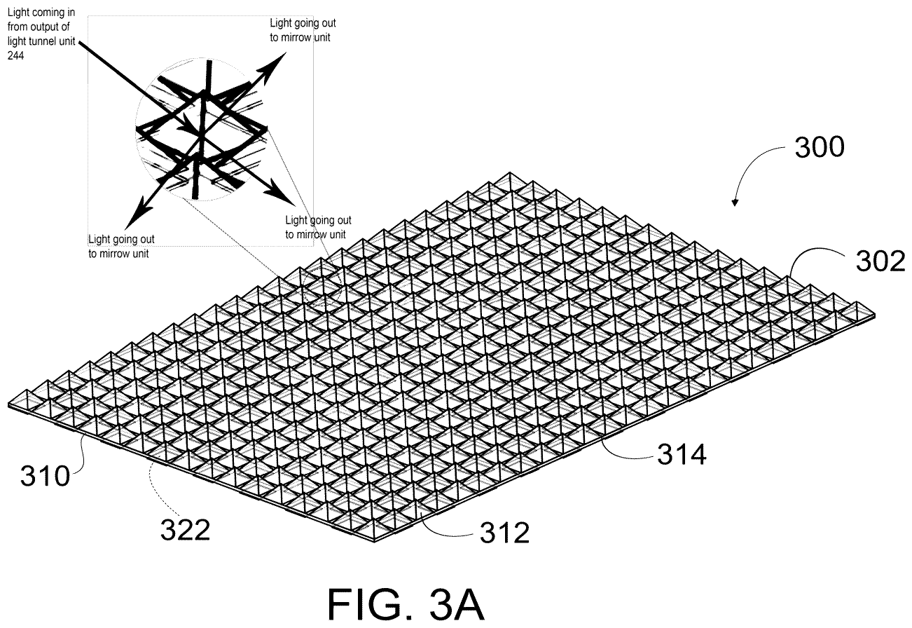

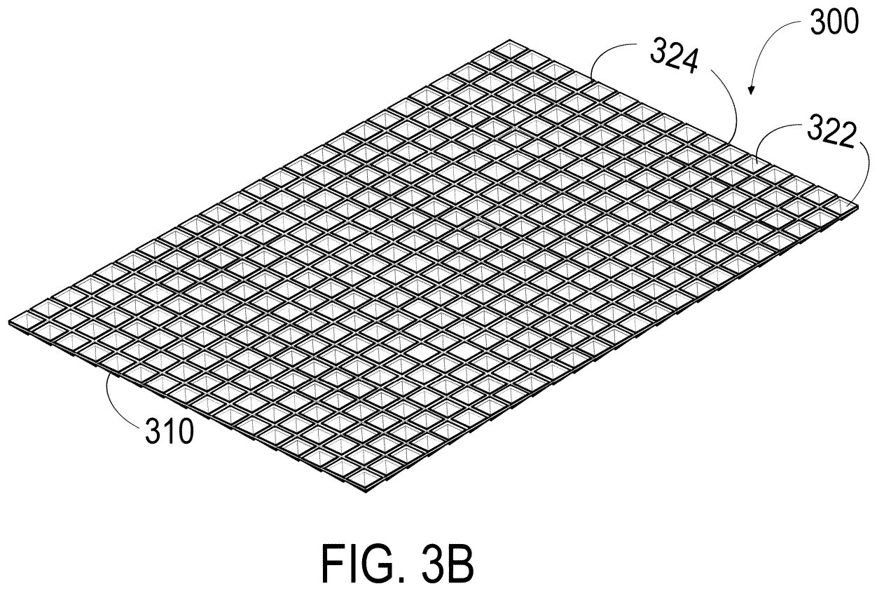

In some embodiments, a light reflecting unit 300 is positioned beneath the internal solar panel 150. The light reflecting unit 300 includes pyramid-shaped grating elements that receive sunlight and distribute it in multiple directions toward the internal solar panel 150. When combined with the mirror unit 500, depicted in FIG. 5, this setup reflects incoming sunlight from the mirror unit 500 back upward toward the pyramid-shaped grating elements of the light reflecting unit 300 and onto the internal solar panel 150, allowing multiple solar panel layers to efficiently capture sunlight. Further description regarding the light reflecting unit 300 is provided with regard to FIGS. 3A and 3B.

FIG. 1B refers to a front view illustration of the external solar panel 100 (e.g., a PV module), in accordance with some embodiments of the present disclosure. The external solar panel 100 receives direct sunlight and converts it to electrical energy. As best seen in FIG. 1B, the external solar panel 100 includes a plurality of discrete PV cells 102 arranged in a plurality of cell rows 104. The cell rows 104 include a first row 104A and a last row 104B. Further, the cell rows 104 are arranged side-by-side, the PV cells 102 and cell rows 104 are electrically connected such that, in operation, current generally flows in a unidirectional manner through the PV cells 102. In the example of FIG. 1B for instance, current generally flows through all of the PV cells 102 from left to right and these cells are electrically connected via conductors commonly referred to as ‘bus bars.’ The resulting electrical output is then directed through terminal 110.

FIG. 1C includes a back view of the solar panel 100, in accordance with some embodiments of the present disclosure. In some embodiments, the back of the solar panel 100 includes a plurality of discrete PV cells 103 arranged in a plurality of cell rows 105. The cell rows 105 include a first row 105A and the last row 105B and they are electrically connected to the front layer (FIG. 1B) through bus bar connectors 113, 115, 117, 119 positioned along the left side of the solar panel. Depending on the embodiment, the solar panel 100 can function as either a monofacial or bifacial solar panel.

In some embodiments, internal solar panel 150 operates similarly to FIG. 1B but facing the opposite direction. It is positioned facing downward to capture sunlight from the light reflecting unit 300 (FIG. 3) and convert it to usable electrical energy. With the light tunnel unit 200 (FIG. 2) positioned at the bottom of the assembly, the internal solar panel 150 is energized as soon as the external solar panel 100 starts converting energy through the reflection of light by the light tunnel 200 (FIG. 2), the mirror unit 500 (FIG. 5) and the light reflecting unit 300 (FIG. 3). FIG. 4 depicts the adhesive support layer 400, which includes a translucent sheet with transparent adhesive materials on both surfaces to serve two functions. First, it secures both solar panels together. Secondly, if bifacial solar cells are being used in the system, the translucent material helps refract sunlight onto the backside of the bifacial solar cells to increase output power.

FIGS. 2A, 2B, and 2C provide a perspective view of a light tunnel unit 200 of the multilayer solar panel system according to an embodiment of the present disclosure. Light tunnel unit 200 is a frame structure that supports diagonal edges to reflect sunlight onto other layers, thus allowing multiple panels to be energized simultaneously. In some embodiments, the light tunnel unit comprises highly transparent materials (such as glass, lenses, acrylic, polyethylene terephthalate (PET), etc.), the light tunnel unit incorporates at least one transparent opening surface referred to as Incoming Light Surface (ILS) to allow the entry of the incoming light. Additionally, the light tunnel unit includes at least one opening surface referred to as outgoing Light Surface (OLS) through which light exits.

Furthermore, in the light tunnel unit, the light enters from the upper side via the ILS and subsequently undergoes reflections throughout its path. The ILS located on top of the light tunnel unit facilitates the entry of light. The lateral surfaces of the light tunnel unit 200 are constructed from reflective material (such as mirror spray coated, mirror thin film or mirror sheet and such) to sidewall surfaces, positioned facing each other allowing for multiple reflections of light within the tunnel. This arrangement ultimately enables the light to exit through the diagonal edges of the OLS.

FIG. 2A offers a top perspective of the light tunnel unit 200 and FIG. 2B offers a bottom perspective of the light tunnel unit 200, in accordance with some embodiments of the present disclosure. The elements of the light tunnel unit 200 comprise the ILS 220, 222, 224, 226, the external surface walls 210, 212, 214, 216, the internal mirror walls 250, 252, 254, 256, the OLS 240, 242, 244, 246 and the diagonal mirror walls 230, 232, 234, 236.

Sunlight enters the light tunnel unit through the various ILS openings 220, 222, 224, 226, and travels downward along the path inside the internal mirror walls 250, 252, 254, 256 at an angled direction, the reflective inner walls ensure that sunlight is consistently redirected to the opposite side of the mirror walls and guided downward onto the diagonal mirror walls 230, 232, 234, 236 and ultimately, light exits through the openings of the OLS 240, 242, 244, 246 and is directed toward the light reflecting unit 300 and the mirror unit 500 as illustrated in FIG. 5.

FIG. 2C illustrates a cross-sectional side view of the light tunnel unit, in accordance with some embodiments of the present disclosure. The cross-sectional side view reflects how light tunnel sections (e.g., external surface walls 210, internal mirror walls 250) reflect the sunlight from the top opening down to the diagonal edges 230, 240 for sunlight to continue onto the light reflecting unit 300 (FIG. 3) and to the mirror unit 500 (FIG. 5).

FIG. 3A offers a top perspective of the light reflecting unit 300 and FIG. 3B offers a bottom perspective of the light reflecting unit 300, in accordance with some embodiments of the present disclosure. In some embodiments, the light reflecting unit 300 receives sunlight from the outgoing light surface (OLS) 240, 242, 244, 246 of the light tunnel unit (FIG. 2) and distributes it through the light reflecting unit 300. In some embodiments, the light reflecting unit 300 includes a plurality of pyramid-shaped grating elements 302 arranged in a grid pattern across the surface.

Sunlight is transmitted through the pyramid-shaped grating elements 302 and the side base portion 310, and subsequently passes through a transparent base gap 314 to impinge upon the mirror unit 500, where the sunlight is reflected along at least two optical paths.

Along a first optical path, the reflected sunlight propagates substantially directly through the transparent base gap 314 and transparent gap 324 formed between adjacent pyramid-shaped grating elements 302 to directly illuminate and energize an internal solar panel.

Along a second optical path, the sunlight is redirected alongside surfaces 312 of the pyramid-shaped grating elements 302 toward the mirror unit 500. The mirror unit 500 reflects the sunlight back upward through the transparent base portion 322 toward the pyramid-shaped grating elements 302. The reflected sunlight is thereby dispersed in multiple directions, directing light onto additional regions of the internal solar panel and increasing effective illumination.

FIG. 4 provides an elevation view of the adhesive support layer 400, in accordance with some embodiments of the present disclosure. The adhesive support layer 400 comprises a translucent sheet with a first adhesive surface 402 and a second adhesive surface 404 positioned on opposite sides of the layer. The first adhesive surface 402 is configured to attach to one solar panel (e.g., external solar panel 100) while the second adhesive surface 404 is configured to attach to another solar panel (e.g., internal solar panel 150), thereby securing both solar panels together. In embodiments where bifacial PV cells are utilized, the translucent material of the adhesive support layer 400 facilitates the refraction of sunlight onto the backside of the bifacial solar cells to increase power output.

FIG. 5 provides an elevation view of a mirror unit 500, in accordance with some embodiments of the present disclosure. The mirror unit 500 includes an incoming light surface 502 and a mirror wall 504. The mirror wall 504 reflects all incoming light regardless of its angle. Sunlight entering through the incoming light surface 502 from the light tunnel unit 200 is reflected off the mirror wall 504 and then dispersed onto the light reflecting unit 300 to supply energy for the internal solar panel 150. The mirror unit 500 redirects all incoming sunlight back toward the light reflecting unit 300 and onto the internal solar panel 150.

References throughout this specification to “one embodiment”, “an embodiment”, “a related embodiment” or similar language mean that a particular feature, structure or characteristic described in connection with the referred to “embodiment” is included in at least one embodiment of the present disclosure. Thus, appearances of the phrases “in one embodiment”, “in an embodiment” and similar language throughout this specification may, but do not necessarily, all refer to the same embodiment. It is to be understood that no portion of disclosure, taken on its own and in possible connection with a figure, is intended to provide a complete description of all features of the disclosed subject matter.

In addition, the following disclosure may reference corresponding drawings, in which like numbers represent the same or similar elements wherever possible. In the drawings, the depicted structural elements are generally not to scale, and certain components are enlarged relative to the other components for purposes of emphasis and understanding. It is to be understood that no single drawing is intended to support a complete description of all features of the disclosed subject matter. In other words, a given drawing is generally descriptive of only some, and generally not all, features of the disclosed subject matter. A given drawing and an associated portion of the disclosure containing a description referencing such drawing do not, generally contain all elements of a particular view or all features that can be presented in this view, for purposes of simplifying the given drawing and discussion, and to direct the discussion to particular elements that are featured in this drawing. A skilled artisan will recognize that the disclosure may possibly be practiced without one or more of the specific features, elements, components, structures, details or characteristics, or with the use of other methods, components, material and so forth. Therefore, although a particular detail of an embodiment of the disclosure may not be necessarily shown in each and every drawing describing such embodiment, the presence of this detail in the drawing may be implied unless the context of the description requires otherwise. In other instances, well known structures, details, materials or operations may not be shown in a given drawing or described in detail to avoid obscuring aspects of an embodiment of the disclosure that are being discussed. Furthermore, the described single features, structures or characteristics of the disclosure may be combined in any suitable manner in one or more further embodiments.

What is claimed is:

1. A multilayer solar panel system comprising:
a first solar panel oriented to receive direct sunlight;
a second solar panel, operatively coupled to the first solar panel, oriented in an opposite direction relative to the first solar panel;
a light tunnel unit, operatively coupled to the first solar panel and the second solar panel, to capture sunlight and guide the sunlight toward a light reflecting unit and a mirror unit;
the light reflecting unit, operatively coupled to the light tunnel unit, to receive the sunlight from the light tunnel unit and distribute the sunlight toward the second solar panel; and
the mirror unit, operatively coupled to the light tunnel unit, to reflect incoming sunlight toward the light reflecting unit and onto the second solar panel.

2. The multilayer solar panel system of claim 1, further comprising an adhesive support layer between the first solar panel and the second solar panel, the adhesive support layer comprising a translucent sheet with a first adhesive surface attached to a back side of the first solar panel and a second adhesive surface attached to a back side of the second solar panel.

3. The multilayer solar panel system of claim 2, wherein the translucent sheet facilitates refraction of sunlight onto a backside of bifacial PV cells.

4. The multilayer solar panel system of claim 1, wherein the first solar panel and the second solar panel comprise at least one of monofacial PV cells or bifacial PV cells.

5. The multilayer solar panel system of claim 1, wherein the first solar panel and the second solar panel comprise a plurality of PV cells interconnected in series, parallel or a combination thereof, based on a desired power and voltage output.

6. The multilayer solar panel system of claim 1, wherein the light tunnel unit comprises an incoming light surface to allow entry of sunlight and an outgoing light surface through which sunlight exits.

7. The multilayer solar panel system of claim 6, wherein the light tunnel unit comprises a plurality of internal mirror walls positioned to reflect sunlight downward and a plurality of diagonal mirror walls to redirect the sunlight toward the outgoing light surface.

8. The multilayer solar panel system of claim 1, wherein one or more lateral surfaces of the light tunnel unit comprise reflective material, wherein the one or more lateral surfaces are positioned facing each other to enable varied reflections of the sunlight within the light tunnel unit.

9. The multilayer solar panel system of claim 1, wherein the light reflecting unit comprises a plurality of grating elements arranged in a grid pattern.

10. The multilayer solar panel system of claim 9, wherein the light reflecting unit comprises a transparent gap formed between adjacent grating elements of the plurality of grating elements, the transparent gap configured to allow sunlight to pass through and directly illuminate the second solar panel.

11. The multilayer solar panel system of claim 9, wherein each grating element of the plurality of grating elements comprises diagonal side surfaces that redirect sunlight toward the mirror unit.

12. The multilayer solar panel system of claim 9, wherein each grating element of the plurality of grating elements comprises a transparent base configured to allow sunlight reflected by the mirror unit to pass through toward the second solar panel.

13. The multilayer solar panel system of claim 9, wherein the plurality of grating elements comprise pyramid-shaped grating elements.

14. The multilayer solar panel system of claim 1, wherein the mirror unit comprises an incoming light surface and a mirror wall to reflect sunlight.

15. A method of assembling a multilayer solar panel system, the method comprising:
orienting a first solar panel to receive direct sunlight;
positioning a second solar panel in an opposite direction relative to the first solar panel;
operatively coupling a light tunnel unit to the first solar panel and the second solar panel, the light tunnel unit to capture sunlight and guide the sunlight toward a light-reflecting unit and a mirror unit;
operatively coupling the light-reflecting unit to the light tunnel unit, the light-reflecting unit to receive sunlight from the light tunnel unit and distribute the sunlight toward the second solar panel; and
operatively coupling the mirror unit to the light tunnel unit, the mirror unit to reflect incoming sunlight toward the light-reflecting unit and onto the second solar panel.

16. The method of claim 15, further comprising positioning an adhesive support layer between the first solar panel and the second solar panel, the adhesive support layer comprising a translucent sheet with a first adhesive surface attached to a back side of the first solar panel and a second adhesive surface attached to a back side of the second solar panel.

17. The method of claim 16, wherein the translucent sheet facilitates refraction of sunlight onto a backside of bifacial PV cells.

18. The method of claim 15, wherein the first solar panel and the second solar panel comprise at least one of monofacial PV cells or bifacial PV cells.

19. The method of claim 15, wherein the first solar panel and the second solar panel comprise a plurality of PV cells interconnected in series, parallel or a combination thereof, based on a desired power and voltage output.

20. The method of claim 15, wherein the light tunnel unit comprises an incoming light surface to allow entry of sunlight and an outgoing light surface through which sunlight exits.
